(19) United States
(12) Patent Application Publication
(10) Pub. No.: US 2015/0221894 A1
(43) Pub. Date: Aug. 6, 2015

(54) ORGANIC LIGHT-EMITTING DIODE AND METHOD OF OPERATING AN ORGANIC LIGHT-EMITTING DIODE

(71) Applicant: OSRAM OLED GmbH, Regensburg (DE)

(72) Inventor: Daniel Steffen Setz, Boeblingen (DE)

(73) Assignee: OSRAM OLED GMBH, Regensburg (DE)

(21) Appl. No.: 14/423,702

(22) PCT Filed: Aug. 21, 2013
(86) PCT No.: PCT/EP2013/067385

§ 371 Date: Feb. 24, 2015

(30) Foreign Application Priority Data
Aug. 24, 2012 (DE) 10 2012 215 113.3

(51) Int. Cl. H01L 51/52; G02B 26/00

(52) U.S. Cl. CPC H01L 51/5275; G02B 26/005; H01L 51/5237

(57) ABSTRACT

In at least one embodiment of the organic light-emitting diode (1), the latter comprises a radiation-permeable carrier (2). On the carrier (2) there is mounted at least one organic active layer (3) provided for the generation of radiation. Also mounted on the carrier (4) is a plurality of liquid lenses (4). In the switched-off state of the active layer (3), the organic light-emitting diode (1) has in respect of visible light a transmittance of at least 0.55 and is pellucid. In the switched-on state of the active layer (3), the liquid lenses (4) are configured for increasing the light outcoupling efficiency of radiation out of the light-emitting diode (1) and the light-emitting diode (1) appears turbid.

An organic light-emitting diode is described. Furthermore, a method of operating such an organic light-emitting diode is described.

This patent application claims the priority of German patent application 10 2012 215 113.3, the disclosure content of which is herewith incorporated by reference.

A problem to be solved is that of providing an organic light-emitting diode having a high light outcoupling efficiency.

That problem is solved inter alia by an organic light-emitting diode and by a method having the features of the independent patent claims. Preferred further developments are the subject matter of the dependent claims.

According to at least one embodiment, the organic light-emitting diode comprises a carrier. The carrier is the component that mechanically carries and mechanically supports the light-emitting diode. The carrier is radiation-permeable, especially to visible light. The carrier is likewise permeable to light that is generated during operation of the organic light-emitting diode. The carrier comprises, for example, one of the materials mentioned below or consists of one or more of these materials: a glass, such as a soda-lime glass, a plastics material, such as polycarbonate, or a ceramic material.

According to at least one embodiment, the organic light-emitting diode contains one or more organic active layers which are provided for the generation of radiation. The at least one active layer is mounted on the carrier. The active layer can comprise or consist of organic polymers, organic oligomers, organic monomers or organic small, non-polymeric molecules, that are known as “small molecules”, or a combination thereof. In the at least one active layer, during operation there is generated, for example, white light or coloured light, such as blue light. If a plurality of active layers are present, different active layers can emit in spectral ranges that are different from one another, so that a mixed radiation can be emitted by the light-emitting diode.

The at least one organic active layer is preferably a constituent of an organic layer sequence. In addition to the active layer, the organic layer sequence can have further functional layers, such as charge carrier transport layers, charge carrier generation layers and/or charge carrier injection layers.

According to at least one embodiment, the organic light-emitting diode comprises a plurality of liquid lenses. The liquid lenses comprise at least one liquid, preferably two liquids. The liquids are configured to be deformed, especially by application of an electrical potential, so that the liquid lenses can be purposively modified in respect of their optical properties, especially in respect of an average refractive power. The liquid lenses are indirectly or directly mounted on the carrier.

According to at least one embodiment, in the switched-off state of the active layer the organic light-emitting diode is permeable to visible light and has a transmittance of at least 0.55 or of at least 0.65 or of at least 0.75. Furthermore, in the switched-off state of the active layer the organic light-emitting diode is pellucid. In other words, the light-emitting diode is transparent during operation of the at least one active layer. It is therefore possible for the organic light-emitting diode, in the switched-off state of the active layer, to appear to an observer to be similar to a window-pane that has not been rendered turbid.

According to at least one embodiment, in the switched-on state of the active layer the organic light-emitting diode is at least temporarily turbid. In other words, during operation of the active layer, to an observer the organic light-emitting diode appears similar to a luminous milk-glass pane.

A turbidity (haziness) value of the organic light-emitting diode can be determined analogously to liquids, especially using a transmitted light measurement. For example, in the switched-off state of the active layer the organic light-emitting diode has, averaged over the area of the light-emitting diode configured for light generation and for light emission, a turbidity value of at most 500 NTU or of at most 3,000 NTU. In the switched-on state, the average turbidity value is, for example, at least 5,000 NTU or at least 15,000 NTU. The optical far-field is a determining factor for the turbidity value.

According to at least one embodiment of the light-emitting diode, in the switched-on state of the active layer the liquid lenses are configured for increasing the light outcoupling efficiency of radiation out of the light-emitting diode. This can be achieved by actuating the liquid lenses in such a way that, in the switched-on state of the active layer, they have a smaller average radius of curvature than in the switched-off state of the active layer. Particularly in the switched-off state, the liquid lenses have a very large average radius of curvature which in an optimum case is infinitely large or almost infinitely large and accordingly does not give rise to any turbidity or modification of the light path.

In at least one embodiment of the organic light-emitting diode, the latter comprises a radiation-permeable carrier.

On the carrier there is mounted at least one organic active layer provided for the generation of radiation. Also mounted on the carrier is a plurality of liquid lenses. In the switched-off state of the active layer, the organic light-emitting diode has in respect of visible light a transmittance of at least 0.55 and is pellucid. In the switched-on state of the active layer, the liquid lenses are configured for increasing the light outcoupling efficiency of radiation out of the light-emitting diode and the light-emitting diode appears turbid (hazy).

The organic light-emitting diode therefore comprises a switchable liquid lens array. The liquid lens array is switched in such a way that in the switched-off state of the active layer the light-emitting diode appears transparent and in the switched-on state of the active layer the radiation outcoupling efficiency is enhanced as a result of the modified surface geometry.

Other possible ways of realising an organic light-emitting diode that is pellucid in the switched-off state lie in the use of light guides having a relatively low light-scattering effect, into which radiation is coupled in the lateral direction. Such light guides have, however, comparatively low optical efficiency. A further possibility lies in the use of thermotropic layers inside the organic light-emitting diode, wherein a scattering effect is adjustable by alteration of the refractive index as a result of temperature changes. The use of thermotropic layers is comparatively expensive, however.

On the other hand, the use of liquid lenses makes it possible to achieve a high optical light outcoupling efficiency in the switched-on state of the active layer and a high degree of transparency in the switched-off state of the active layer.

Liquid lenses are based on what is known as electrowetting. This enables an angle of contact between a liquid and a solid to be reversibly modified by the application of an electrical voltage. By adjustment of the electrical voltage it is possible to adjust the contact angle so that either lenses are formed in the liquid or the surface of the liquid is flat, with the result that scattering of light can be prevented.

The liquid lenses are constructed and produced, for example, as indicated in the publication N. R. Smith et al., Journal of Display Technology, Vol. 5, No. 11, November 2009. The disclosure content of that publication is incorporated by reference.

According to at least one embodiment of the organic light-emitting diode, at least some of the liquid lenses or all of the liquid lenses are located on a side of the active layer remote from the carrier. In other words, the active layer is in that case arranged between the liquid lenses and the carrier.

According to at least one embodiment, the liquid lenses are located on an underside of the carrier remote from the active layer. In that case the carrier is arranged between the liquid lenses and the active layer.

According to at least one embodiment, the liquid lenses are mounted on the carrier on both sides of the active layer. The liquid lenses can therefore be located both on the side of the carrier remote from the active layer and on the side of the active layer remote from the carrier.

According to at least one embodiment, the liquid lenses have an average width of at least 10 μm or of at least 25 μm or of at least 75 μm. The average width corresponds to an average diameter of the liquid lenses in the direction parallel to a direction of main extent of the active layer. Alternatively or additionally, the average width is at most 500 μm or at most 250 μm or at most 150 μm.

According to at least one embodiment, the liquid lenses have an average thickness of at least 10 μm or of at least 25 μm or of at least 50 μm. Alternatively or additionally, the average thickness is at most 250 μm or at most 100 μm or at most 50 μm. The average thickness can relate either to the total liquid lens or only to the liquids of the liquid lenses.

According to at least one embodiment of the organic light-emitting diode, the liquid lenses each have electrodes. In particular, the liquid lenses are each provided with two electrodes that are different from one another. At least one or both of the electrodes of the liquid lenses are made from a radiation-permeable material. For example, the material for the electrodes is a transparent, conductive oxide, such as indium tin oxide, abbreviated to ITO. It is in that case possible for all of the liquid lenses to consist only of radiation-permeable materials.

According to at least one embodiment, the liquid lenses cover at least 60% or at least 80% or at least 90% of the active layer, seen in plan view. It is likewise possible for the liquid lenses to cover all of the active layer, at least in a region of the organic light-emitting diode provided for light outcoupling. It is also possible for adjacent liquid lenses to be in interlocking contact in a direction parallel to directions of main extent of the active layer. In particular, there are no gaps between adjacent liquid lenses, seen in plan view.

According to at least one embodiment of the light-emitting diode, the liquid lenses have two liquids layered one above the other. “Layered one above the other” means that the liquids follow one another in the direction away from the active layer. The liquids layered one above the other have different optical refractive indices from one another. The refractive indices are especially determined at a peak wavelength of the radiation generated by the organic light-emitting diode during operation.

According to at least one embodiment, that liquid which is located closer to the active layer has a higher refractive index.

According to at least one embodiment, the liquid that is located closer to the active layer has an optical refractive index that is higher than or is the same as the refractive index of the carrier and/or of an encapsulating layer of the organic light-emitting diode.

According to at least one embodiment, a proportion by area of the liquids of the liquid lenses, based on an area of the active layer and seen in plan view, is at least 60% or at least 70% or at least 80%. In other words, an overwhelming proportion of the area of the active layer is covered by the liquids of the liquid lenses.

According to at least one embodiment, at least one of the electrodes of the liquid lenses is aligned parallel to at least one active layer. This applies especially to that electrode which is located on a side of the liquid lenses remote from the active layer. The further electrode can be oriented perpendicular to the active layer.

According to at least one embodiment, the liquid lenses are arranged laterally adjacent and regularly in a matrix, also referred to as an array. The arrangement can be effected, for example, in a regular rectangular, triangular or hexagonal grid.

According to at least one embodiment, an area of the matrix of the liquid lenses is at least 50 cm² or at least 100 cm² or at least 200 cm². This area is preferably a contiguous area. It is possible for that area to be continuous and uninterrupted.

According to at least one embodiment, at least some of adjacent liquid lenses do not directly abut one another. A region between those adjacent liquid lenses, seen in plan view, is in that case partly or fully radiation-permeable. In other words, between the liquid lenses there are no regions that are purposively radiation-impermeable.

According to at least one embodiment, the liquid lenses, seen in plan view, are not circular in shape. In particular, the liquid lenses, seen in plan view, have a square, rectangular, triangular or hexagonal basic shape.

According to at least one embodiment of the light-emitting diode, all the liquid lenses or all the liquid lenses on one side of the active layer are electrically connected in parallel. Alternatively thereto, it is possible for the liquid lenses to be connectable and actuable independently of one another region-wise, for example to form symbols or pictograms.

According to at least one embodiment, the liquid lenses are configured only for low electrical switching times. For example, a minimum time within which the liquid lenses are switchable from a state of minimum curvature to a state of maximum curvature is at least 100 ms or at least 250 ms or at least 500 ms. In other words, the organic light-emitting diode is in that case not configured for displaying moving images, such as films. Due to the fact that the liquid lenses are switchable only relatively slowly, the materials used for the electrodes of the liquid lenses can be materials having comparatively poor electrical conductivity, such as transparent, conductive oxides. It is therefore possible to tolerate long electrical switching times in order to benefit from a high radiation permeability of the liquid lenses overall.

According to at least one embodiment, all the liquid lenses or all the liquid lenses on one side of the active layer are of identical construction within the limits of manufacturing tolerances. In that case, in particular there are no liquid lenses present which are configured for transmission of radiation components of different colours or polarisation.

According to at least one embodiment, the light-emitting diode is free of a liquid crystal matrix and/or free of polarisation-dependently reflective components, such as mirrors in conjunction with λ-quarter units.

Furthermore, a method of operating an organic light-emitting diode is described. The method is configured especially for operating a light-emitting diode as described in connection with one or more of the above-mentioned embodiments. Features of the light-emitting diodes are therefore disclosed also for the method and vice versa.

In at least one embodiment of the method, in the switched-on state of the active layer the liquid lenses are actuated temporarily or continuously in such a way that an average radius of curvature of the liquid lenses is at most 50 mm or at most 25 mm or at most 5 mm or at most 1 mm or at most 0.4 mm. Furthermore, in the switched-off state of the active layer the liquid lenses are actuated temporarily or continuously in such a way that the average radius of curvature of the liquid lenses is at least 100 mm or at least 250 mm or at least 1 m. In other words, in the switched-on state of the active layer the surfaces of the liquids of the liquid lenses are at least temporarily comparatively strongly curved and in the switched-off state of the active layer they are at least temporarily comparatively slightly curved or flat.

According to at least one embodiment of the method, during operation of the active layer the liquid lenses on different sides of the active layer are actuated temporarily or continuously in such a way that the liquid lenses on different sides of the active layer have different average radii of curvature from one another. It is thereby possible for light outcoupling efficiencies at the two main sides of the organic light-emitting diode to be adjusted relative to one another. It is thereby also possible for an emission intensity at the main faces to be purposively regulated by virtue of the radii of curvature of the liquid lenses.

An organic light-emitting diode described herein and a method described herein will be explained in detail below on the basis of exemplary embodiments and with reference to the drawing. In the individual Figures, elements that are identical are denoted by identical reference numerals, but are not shown to scale; rather, the size of individual elements may have been shown exaggerated for the purpose of better understanding.

In the drawings:

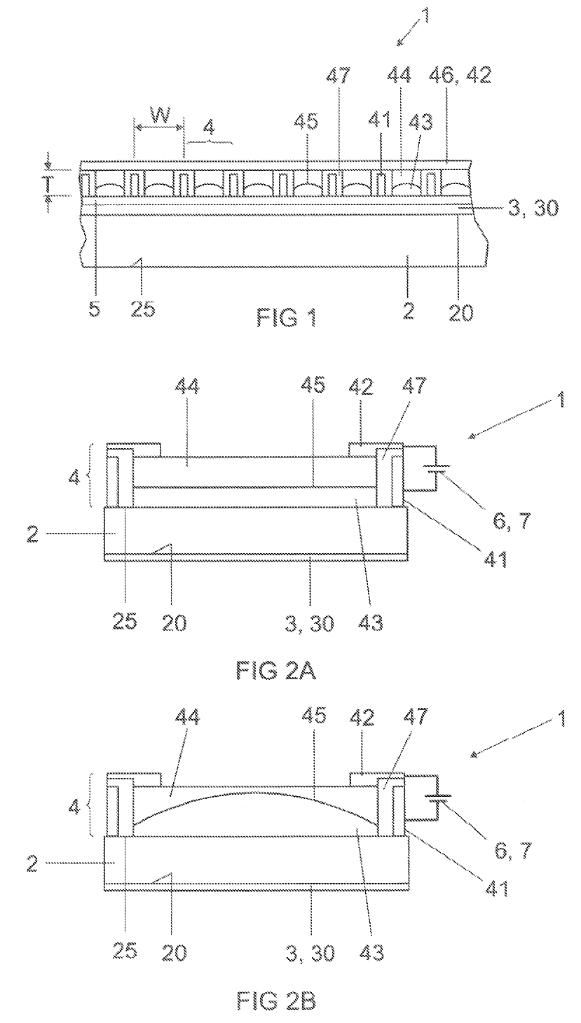

FIGS. 1, 3, 4 and 5 are schematic views of exemplary embodiments of organic light-emitting diodes described herein, and

FIG. 2 is a schematic representation of a method described herein for operating an exemplary embodiment of an organic light-emitting diode described herein.

FIG. 1 shows a schematic sectional view of an exemplary embodiment of an organic light-emitting diode 1. The light-emitting diode 1 comprises a radiation-permeable, preferably pellucid, carrier 2. The carrier 2 has a carrier upper side 20 and, opposite thereto, a carrier underside 25.

On the carrier upper side 20 there is mounted an organic layer sequence 30 having at least one organic active layer 3 provided for the generation of radiation. In the direction away from the carrier 2, the organic layer sequence 30 is followed by a radiation-permeable encapsulating layer 5.

On a side of the encapsulating layer 5 remote from the carrier 2 there is mounted a plurality of liquid lenses 4. The liquid lenses 4 each have two liquids 43, 44 layered one above the other. The liquid 43 located closer to the organic layer sequence 30 is, for example, a radiation-permeable oil or a fluoropolymer. Water or an aqueous liquid can serve as the liquid 44 located further from the organic layer sequence 40. That liquid 44, unlike the liquid 43, is preferably a polar liquid.

The liquid 43 located closer to the active layer 3 preferably has a higher refractive index than the liquid 44 and than the carrier 2 or the encapsulating layer 5. An average width W of the liquid lenses 4 is, for example, approximately 400 μm. An average thickness T of the liquid lenses 4 is, for example, approximately 200 μm.

Furthermore, the liquid lenses 4 each comprise two electrodes 41, 42. The first electrodes 41, which are located closer to the organic layer sequence 30, surround the associated liquids 43, 44 on all sides. The first electrodes 41 are aligned substantially perpendicularly to the organic layer sequence 30. Adjacent liquid lenses 4 can share first electrodes 41.

On the side of the liquid lenses 4 remote from the organic layer sequence 30 there is located the second electrode 42, which can also form a cover layer 46 of the liquid lenses 4. The second electrode 42 is preferably an electrode that is continuous and common to all liquid lenses 4. Both electrodes 41, 42 are preferably formed from radiation-permeable materials.

The electrodes 41, 42 are electrically insulated from one another by an insulating layer 47 which is preferably formed from a transparent material. The insulating layer 47 is located in addition between the liquids 43, 44 and the first electrode 41.

FIG. 2 illustrates, schematically in sectional views, a further exemplary embodiment of the light-emitting diode 1 and a method of operating the light-emitting diode 1.

According to FIG. 2A, the active layer 3 is not in operation, so that no radiation is being generated in the active layer 3. In this state the liquid lenses 4 are actuated at least temporarily in such a way that an interface 45 between the liquids 43, 44 is substantially flat. Actuation is effected by a power supply 6 in conjunction with an actuating unit 7, each being shown only in simplified form. In this state of the liquid lenses 4, the liquid lenses 4 have no light-scattering effect or no significant light-scattering effect, so that the light-emitting diode 1 appears pellucid.

FIG. 2B shows the state of the liquid lenses 4 while the active layer 3 is generating radiation. The liquid lenses 4 are actuated in such a way that the liquid 43 is shaped similarly to a converging lens. The interface 45 between the liquids 43, 44 is convexly curved.

For ease of illustration, only one of the liquid lenses 4 is shown in FIG. 2. Furthermore, electrical supply lines and electrical connections, for example for the organic layer sequence 30, as also in the other Figures, are shown only in highly simplified form or are not shown at all.

According to FIG. 2, the liquid lenses 4 are located on the underside 25 of the carrier 2 remote from the active layer 3. As also in all other exemplary embodiments, it is possible for the electrodes 41, 42, seen in plan view onto the active layer 3, to constitute only a comparatively small proportion by area, based on the active layer 3. Therefore only a comparatively small portion of the liquids 43, 44 is covered by the second electrode 42. An optional cover layer over the second electrode 42 and over the liquids 43, 44 is not shown in the drawing.

Departing from what is shown, it is also possible for the second electrode 42 to be located between the liquids 43, 44 and the carrier 2. Other geometries are also possible for the electrodes 41, 42, for example as indicated in the publication T. Krupenkin et al., Nature Communications, DOI: 10.1038/ncommsl454, the disclosure content of which is incorporated by reference.

The encapsulating layer 5 can also be realised by a plurality of partial layers. In particular, by means of the encapsulating layer 5 it is possible to effect electrical separation of the liquid lenses 4 from the organic layer sequence 30.

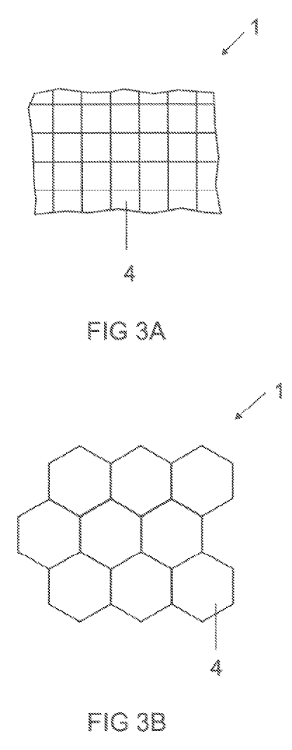

FIG. 3 shows schematic plan views of exemplary embodiments of the light-emitting diodes 1. According to FIG. 3A, the liquid lenses 4 are arranged in a regular, square grid. According to FIG. 3B, the arrangement grid is hexagonal.

As also in all other exemplary embodiments, it is possible for adjacent liquid lenses 4 to directly abut one another so that there is no gap between adjacent liquid lenses 4, seen in plan view. Departing from what is shown according to FIG. 3 it is also possible, however, for a preferably radiation-permeable region to be located between adjacent liquid lenses 4, seen in plan view.

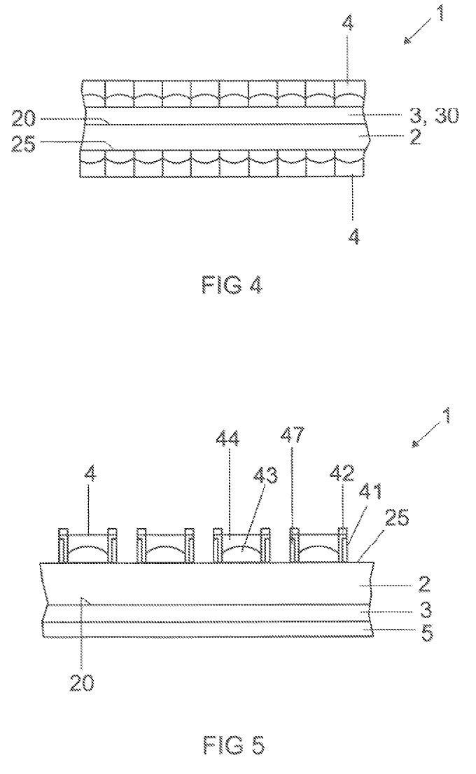

In the exemplary embodiment according to FIG. 4, the liquid lenses 4 are located on both sides of the organic layer sequence 30. The liquid lenses 4 on each side of the carrier 2 can be electrically actuated independently of one another. It is thereby possible to set different radii of curvature at the liquid lenses 4 on each side of the carrier 2. As a result, during operation of the active layer 3 it is possible to adjust the light outcoupling efficiency side-dependently and accordingly also to regulate distribution of the radiation emitted by the light-emitting diode 1.

In the exemplary embodiment according to FIG. 5, the liquid lenses 4 are not arranged directly adjacent. The regions located between adjacent liquid lenses 4 are preferably pellucid in respect of visible light. As also in all other exemplary embodiments, individual liquid lenses 4 or a plurality of the liquid lenses 4 can be actuated separately in order, for example, to form symbols in the switched-off and/or in the switched-on state of the active layer 3.

The invention described herein is not limited by the description with reference to the exemplary embodiments, but rather the invention encompasses any novel feature and any combination of features, including in particular any combination of features in the patent claims, even if that feature or that combination is not itself explicitly described in the patent claims or exemplary embodiments.

1. Organic light-emitting diode having
a radiation-permeable carrier,
at least one organic active layer provided for the generation of radiation, which active layer is mounted on the carrier, and
a plurality of liquid lenses which are mounted on the carrier,
wherein
in the switched-off state of the active layer the organic light-emitting diode has a transmittance of at least 0.55 for visible light and is pellucid, and
in the switched-on state of the active layer the liquid lenses are configured for increasing the light outcoupling efficiency of radiation out of the light-emitting diode and the light-emitting diode is turbid.

2. Organic light-emitting diode according to claim 1,
wherein at least some of the liquid lenses are located on a side of the active layer remote from the carrier.

3. Organic light-emitting diode according to claim 1,
wherein the liquid lenses are mounted on the carrier on both sides of the active layer.

4. Organic light-emitting diode according to claim 1,
wherein the liquid lenses have an average width (W) between 10 μm and 500 μm inclusive and an average thickness (T) of the liquid lenses between 10 μm and 250 μm inclusive.

5. Organic light-emitting diode according to claim 1,
wherein the liquid lenses have electrodes which are made from a radiation-permeable material.

6. Organic light-emitting diode according to claim 1,
wherein the liquid lenses, seen in plan view, cover at least 80% of the active layer.

7. Organic light-emitting diode according to claim 1,
wherein the liquid lenses have two liquids layered one above the other having refractive indices that are different from one another,
the liquid with the higher refractive index being located closer to the active layer and having a higher refractive index than the carrier.

8. Organic light-emitting diode according to claim 7,
wherein a proportion by area of the liquids, based on an area of the active layer and seen in plan view, is at least 60%.

9. Organic light-emitting diode according to claim 1,
wherein the electrode located on a side remote from the active layer is at least in some places aligned parallel to the active layer.

10. Organic light-emitting diode according to claim 1,
wherein the liquid lenses are arranged laterally adjacent and regularly in a matrix, an area of the matrix being at least 50 cm².

11. Organic light-emitting diode according to claim 1,
wherein a region between adjacent liquid lenses, seen in plan view, is at least partly radiation-permeable.

12. Organic light-emitting diode according to claim 1,
wherein liquid lenses, seen in plan view, are not circular in shape.

13. Method of operating an organic light-emitting diode according to claim 1,
wherein the liquid lenses are actuated at least temporarily in such a way that in the switched-on state of the active layer they have an average radius of curvature of at most 50 min and in the switched-off state of the active layer an average radius of curvature of at least 100 mm.

14. Method according to claim 13 for operating an organic light-emitting diode,
wherein the liquid lenses on different sides of the active layer, during operation thereof, are actuated at least temporarily with average radii of curvature that are different from one another.
